(19) United States
(12) Patent Application Publication
(10) Pub. No.: US 2022/0361366 A1
(43) Pub. Date: Nov. 10, 2022

(54) TANK PROVIDING COOLING BY IMMERSION, IMMERSION COOLING DEVICE, AND IMMERSION COOLING EQUIPMENT

(71) Applicant: Fulian Precision Electronics (Tianjin) Co., LTD., Tianjin (CN)

(72) Inventors: CHUNG-CHENG HSIEH, New Taipei (TW); CHANG-WEN CHI, New Taipei (TW); CHIEH-CHEN CHEN, New Taipei (TW); YI-YANG LIAO, Taipei City (TW); YU-FENG CHIEN, Taipei City (TW); JIA-HONG WU, New Taipei (TW)

(21) Appl. No.: 17/740,943

(22) Filed: May 10, 2022

(30) Foreign Application Priority Data
May 10, 2021 (CN) 202110506604.3

(51) Int. Cl. H05K 7/20

(52) U.S. Cl. CPC H05K 7/20236; H05K 7/20763

(57) ABSTRACT

An immersion cooling equipment includes an immersion cooling device, a heating component and a cooling liquid. The immersion cooling device includes a tank providing cooling by immersion and a liquid supply equipment. The tank providing cooling by immersion communicates with the liquid supply equipment and accommodates the heating component and the cooling liquid. The tank providing cooling by immersion includes a mounting bracket, a cooling box, and a sealing plate. The cooling box is positioned in the mounting bracket, the cooling box comprising a plurality of walls, the plurality of walls surround a reception space, the reception space comprising a first opening. The sealing plate is detachably connected or rotatably connected the cooling box, and is used to close or reveal the first opening. Each the walls is made of thermoplastic plastic, and any two abutting walls are fixed by plastic welding.

### CROSS-REFERENCE TO RELATED APPLICATIONS

This application claims priority to Chinese Patent Application No. 202110506604.3 filed on May 10, 2021, filed in China National Intellectual Property Administration, the contents of which are incorporated by reference herein.

### FIELD

The subject matter herein relates to the field of heat dissipation, especially relates to a tank providing cooling by immersion, an immersion cooling device and an immersion cooling equipment.

### BACKGROUND

An immersion liquid cooling server is one of the effective ways to achieve savings in “green” energy consumption. But the cooling box is generally made of stainless steel. The cooling box is sealed by welding, which is labor-intensive and time-consuming, low effectiveness, and high cost.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of a tank providing cooling by immersion of an embodiment according to the present disclosure, showing sealing plates in an open state.

FIG. 2 is an isometric view of the tank, showing the sealing plates in a closed state.

FIG. 3 is a schematic exploded view of an immersion cooling device in an embodiment according to the present disclosure.

FIG. 4 is a schematic view of a welding structure of a wall in the tank shown in FIG. 1.

FIG. 5 is a schematic exploded view of an immersion cooling equipment in an embodiment according to the present disclosure.

### DETAILED DESCRIPTION

In order to make the above-mentioned objects, features, and advantages of the present application more obvious, a description of specific embodiments of the present application will be described with reference to the accompanying drawings. The present application can be implemented in many ways different from those described herein, and those skilled in the art can make similar improvements without violating the contents of the present application. Therefore, the present application is not to be considered as limiting the scope of the embodiments to those described herein.

Several definitions that apply throughout this disclosure will now be presented.

Unless otherwise defined, all technical and scientific terms used herein have the same meaning as commonly understood by one skilled in the art. The terms used in the present application herein are only for describing specific embodiments, and are not intended to limit the present application.

A tank providing cooling by immersion of embodiment is provided for containing cooling liquid to soak heating components. The tank providing cooling by immersion includes a mounting bracket, a cooling box and a plurality of sealing plates. The cooling box is arranged in the mounting bracket and the cooling box includes a plurality of walls. The plurality of walls cooperatively define a reception space. The reception space has a first opening. The sealing plate is detachably connected or rotatably connected with the cooling box, and is used to cover or reveal the first opening. Each wall is made of thermoplastic plastic, and any two abutting against walls are fixed by plastic welding.

It should be noted that plastic welding is generally used in thermoplastic plastic sheet (such as PP, modified PP, PE, PET, etc.). Compared with metal material such as stainless steel, the thermoplastic plastic has the advantages of low density, easy processing, and easy welding. It has excellent chemical resistance, heat resistance, and shock resistance. The plastic welding sheet is usually adopted in electric heating, and air or gas is forced through and heated by a welding gun, heated to the temperature required for welding plastic, and then the weldment and welding rod are heated with this preheated gas to make them stick together in thick stacks and combine.

As described above, a plurality of walls made of the thermoplastic plastic are welded by means of plastic welding. In this disclosure, the welding method of full welding is adopted, and all the places where the two structures are in contact are welded. In the background a stainless steel is installed. The welding used in this application is the welding of plastics. The tank providing cooling by immersion with plastic welding process for better sealing. Due to good sealing effect of plastic welding, leaks of the cooling liquid in the cooling box are uncommon, which is beneficial to improve the service life of the product. The cooling box is made of plastic, the weight of the cooling box is reduced. The connection method of plastic welding also improves the welding effectiveness of the tank providing cooling by immersion, therefore improving the production effectiveness. Compared with a stainless steel, the price of the liner formed by thermoplastic plastic is about one-third of the stainless steel, reducing the production cost of the tank providing cooling by immersion.

Some embodiments of the present application will be described in detail below with reference to the accompanying drawings. The embodiments described below and features in the embodiments may be combined with each other without conflict.

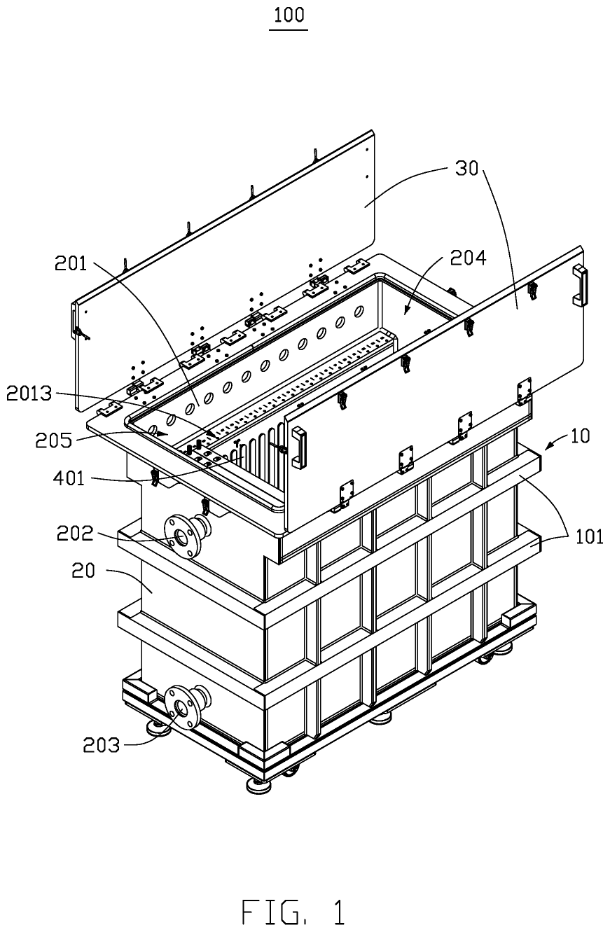

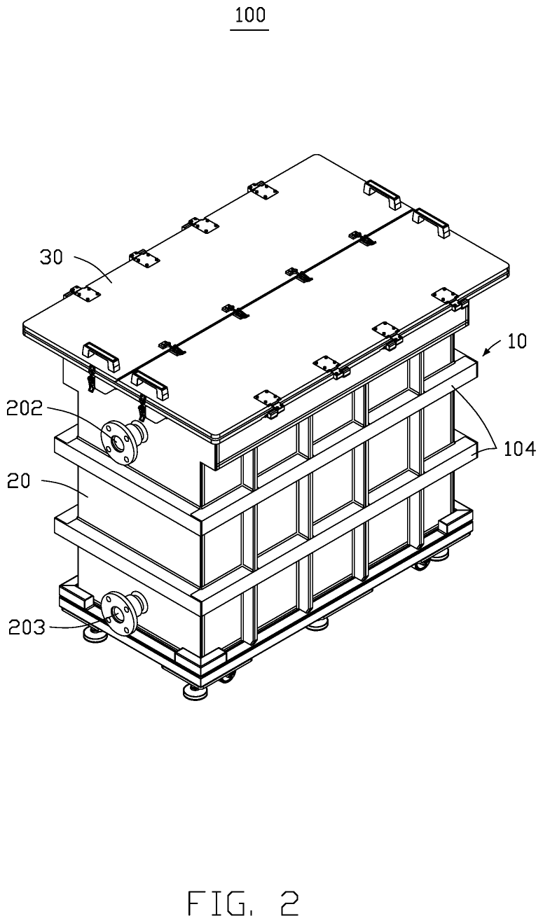

Referring to FIGS. 1-3, a tank providing cooling by immersion 100 of an embodiment is provided for accommodating a cooling liquid (not shown) to immerse a heat-generating component (heating component 300). The tank providing cooling by immersion 100 includes a mounting bracket 10, a cooling box 20, and a sealing plate 30. The cooling box 20 is arranged in the mounting bracket 10, the sealing plate 30 is connected with the cooling box 20. Further, the sealing plate 30 is detachably connected or rotatably connected with the cooling box 20.

The mounting bracket 10 includes a plurality of connecting strips 101, and the connecting strips 101 are spliced to form a frame structure that matches outer contour of the cooling box 20, so that the cooling box 20 can be accommodated therein. When the cooling box 20 is arranged in the mounting bracket 10, the connecting strips 101 are attached to the surface of the cooling box 20 to support the cooling box 20. In an embodiment, the outer contour of the cooling box 20 is rectangular, the connecting strips 101 are spliced to form a rectangular frame.

In an embodiment, the connecting strips 101 is a hollow tubular structure. In other embodiment, each connecting strip 101 is a hollow tubular structure with a rectangular cross-section. By making the connecting strips 101 hollow, it can reduce the overall weight of the mounting bracket 10 and reduce the cost of the mounting bracket 10. It can be understood that, the connecting strips 101 can also be replaced with a hollow tubular structure with a cross-section of other shapes, such as a circular shape. Further, by setting the connecting strips 101 in a hollow tubular structure, the load of the mounting bracket 10 is reduced, thus improving the service life of the tank providing cooling by immersion 100. It can understood that, the mounting bracket 10 can be set in various shapes and structures, so as to improve the load-bearing and pressure-bearing capacity of the mounting bracket 10.

In other embodiment, the connecting strips 101 can also be set as a solid tubular structure, the mounting bracket 10 to better support the cooling box 20. The connecting strips 101 for solid tubular structure can improve the overall strength of the mounting bracket 10.

The cooling box 20 includes a plurality of walls 201. The walls 201 define a reception space 204. The reception space 204 has a first opening 205, the first opening 205 communicating with the reception space 204. Each wall 201 is made of thermoplastic plastic, and any two abutting against walls 201 are fixed by plastic welding. Any two of the walls are connected each other fixed by plastic welding.

It should be noted that the cooling box 20 has the reception space 204 for accommodating the cooling liquid and the heating component 300, after opening the sealing plate 30. The heating component 300 can be put into the cooling box 20 from the first opening 205, and the cooling liquid in the cooling box 20 soaks the heating component 300. The cooling liquid 70 can achieve the purpose of cooling the heating component 300.

In the tank providing cooling by immersion 100 provided above, walls 201 made of the thermoplastic plastic are welded by means of plastic welding. The tank providing cooling by immersion 100 has better sealing. The cooling liquid in the cooling box 20 is not easy to leak. The density of thermoplastic plastic is about 0.90 g/cm³, the density of stainless steel is 7.93 g/cm³. Considering that the thickness of the thermoplastic plastic is 4 times that of the stainless steel: 1−(0.90*4)/7.93=0.54, the weight of the inner using the plastic welding is reduced 54%, thus reducing the weight of the cooling box 20, which is beneficial to improve the service life of the product. Using of the plastic welding also makes the welding effectiveness of the tank providing cooling by immersion 100. Improving the production efficiency of the tank providing cooling by immersion 100 and reducing the production cost of the tank providing cooling by immersion 100. Further, the plastic welding liner is applied to the mounting bracket 10. Under the premise of the satisfying the pressure and bearing requirements, the price of the plastic welding liner and the rectangular connecting strips 101 is about 33% of the stainless steel and the rectangular connecting strips 101. The cost of the tank providing cooling by immersion 100 is reduced.

In an embodiment, the sealing plate 30 and the cooling box 20 can be connected through a detachable connection structure, or directly through a buckle to achieve the connection. The connection structure can be a combination of pins, screws, and nuts, etc. It should be noted that, the sealing plate 30 can be snap-fitted on the cooling box 20, which can be achieved by a buckle.

The sealing plate 30 and the cooling box 20 also can be connected through a rotatable connection. In an embodiment, one of end the sealing plate 30 be hinged to the one of the wall 201 of the plurality of walls 201. The sealing plate 30 can close and seal the first opening 205. The sealing plate 30 is connected the wall 201 by articulating, it is convenient for staff to check inside condition of the cooling box 20, when the sealing plate 30 is opened or closed. Further, in an embodiment, the tank providing cooling by immersion 100 includes two sealing plates 30, the two sealing plates 30 are arranged on the two walls 201. The two sealing plates 30 are respectively hinged on the walls 201. The two sealing plates 30 can be relatively opened or closed, so as to close the first opening 205 or reveal the first opening 205. The opened sealing plate 30 can be kept parallel to the wall 201, the operator can maintain the heating component 300 inside from both side of the cooling box 20.

It can be understood that, in an embodiment, the two sealing plates 30 can be an integral whole sealing plate 30. The integral whole sealing plate 30 also can close the first opening 205 or reveal the first opening 205. In other words, the two sealing plates 30 are made of one plate.

The junction of the sealing plate 30 and the wall 201, is equipped with a sealing washer (not shown). By setting the sealing washer, the junction of the sealing plate 30 and the wall 201 to avoid after the evaporation of the cooling liquid 70 released from the junction.

In some embodiments, the sealing plate 30 is made of a transparent material.

In some embodiments, at least one wall 201 of the plurality of walls 201 is made of a transparent material.

In some embodiments, the sealing plate 30 and at least one wall 201 of the plurality of walls 201 are made of a transparent material.

By setting at least one of the sealing plate 30 and the wall 201 to be transparent, it is convenient for staff to check the inside condition of the cooling box 20.

In some embodiments, the walls 201 includes any two walls 201, and any two walls 201 are abutting against. Two V-shaped welds are formed between the two walls 201 abutting against each another. Weld spot is at the V-shaped weld.

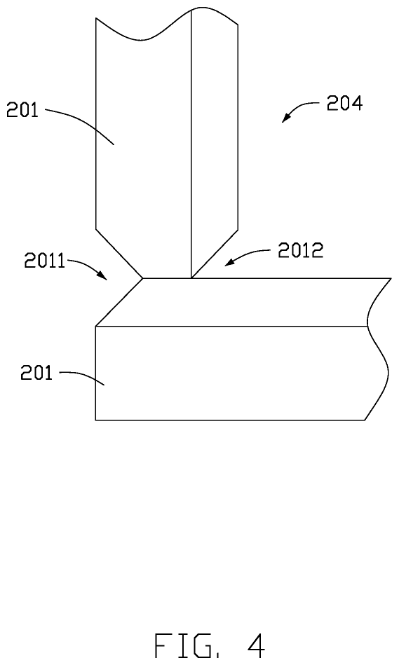

Referring to FIG. 4, a first V-shaped weld 2012 and a second V-shaped weld 2011 is formed between the two abutting against walls 201. The first V-shaped weld 2012 is formed with the opening to face the reception space 204. The second V-shaped weld 2011 is formed with the opening to face an exterior of the cooling box 20. The two V-shaped welds include the first V-shaped weld 2012 and the second V-shaped weld 2011. During the process of welding, plastic welding operation is performed simultaneously on the first V-shaped weld 2012 and the second V-shaped weld 2011. This renders the combination of the two walls 201 firmer, so as to ensure the strength and sealing of the cooling box 20.

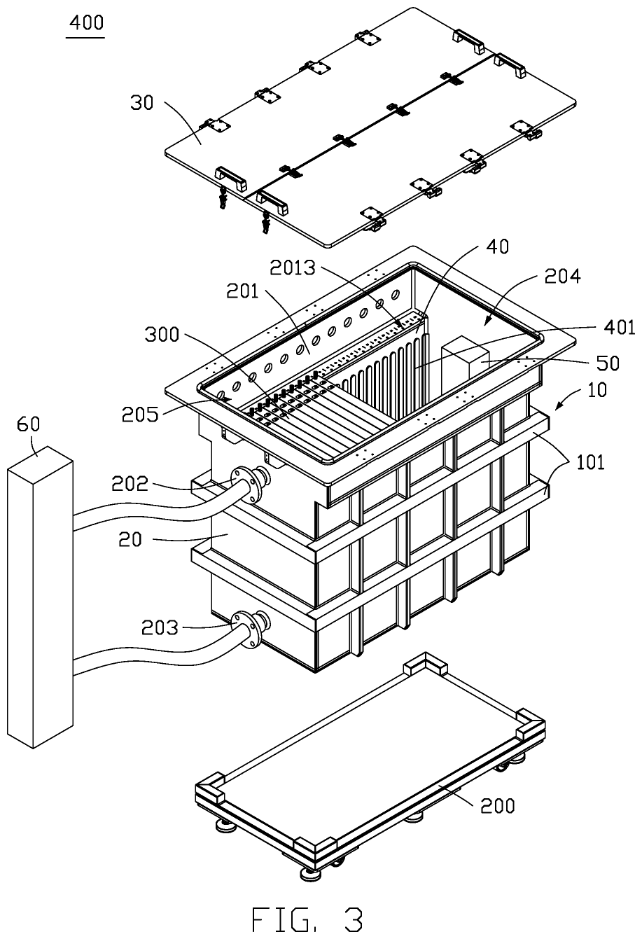

Referring to FIGS. 1 and 3, in an embodiment, the immersion cooling grove 100 includes a fixing mount 40. The fixing mount 40 is arranged in the cooling box 20. The fixing mount 40 is provided with a fixing groove 41. The fixing groove 41 is defined in the fixing mount 40 and configured for receiving the heating component 300.

The shape and size of the fixing groove 401 can be set according to the shape and size of the heating component 300, the fixing groove 401 can adapt to the heating component 300. The heating component 300 positioned in the fixing grove 401 on the fixing mount 40 is thus movable. The heating component 300 is installed more stably. The installation is effective and achieves better heat dissipation.

In an embodiment, the cooling box 20 defines an inlet port 202 and an outlet port 203 to input and output the cooling liquid 70. By inputting the cooling liquid 70 to the inlet port 202 and by outputting the cooling liquid 70 to the outlet port 203, the cooling liquid 70 in the cooling box 20 is circulated in the system. Heat dissipation results of the heating component 300 in the cooling box 20 are thus improved.

It should be noted that, the cooling circulation system includes a pump body and a circulating line, and the circulating line is connected to the pump body. The circulating line is connected the inlet port 202 and the outlet port 203. The pump body inputs the cooling liquid 70 from the inlet port 202 to the cooling box 20 through the circulating line. The pump body outputs the cooling liquid 70 in the cooling box 30 from the outlet port 203 through the circulating line.

Further, the wall 201 is evenly provided with a plurality of through holes 2013 close to the end of the sealing plate 30. The through holes 2013 communicate with the inlet port 202 to allow the cooling liquid 70 to inundate the heating component 300. The through holes 2013 each have the same size and shape, and are arranged along the length direction of the wall 201. The cooling liquid 70 flows roughly the same volume to any one of several heating component 300. When a plurality of heating components 300 are provided in the cooling box 20, and the plurality of heating components 300 are arranged in a certain order. The heating component 300 at locations away from the inlet port 202 contact the cooling liquid 70 at a slower rate than the heating component 300 at locations close to the inlet port 202. By setting the through hole 2013, which communicate with the inlet port 202, each heating component 300 can be flooded by the cooling liquid 70 at the same time, so as to achieve the purpose of cooling the plurality of through holes 2013 at the same time.

In an embodiment, the immersion cooling grove 100 also includes a filler 50. The filler 50 is arranged in the cooling box 20 to fill extra space of the cooling box 20. The filler 50 can reduce the required volume of the cooling liquid 70, and a lower volume of cooling liquid 70 reacts more quickly to being heated and being cooled.

The filler 50 is arranged in the cooling box 20, and the filler 50 is placed in the extra space of the cooling box 20. When the cooling liquid 70 is input into the cooling box 20, the volume of the cooling liquid 70 can be reduced, so as to reduce the use of the cooling liquid 70 and reduce the cost of the tank providing cooling by immersion 100.

In an embodiment, the tank providing cooling by immersion 100 also includes a resistance temperature detector (no shown). The resistance temperature detector is arranged in the cooling box 20 to detect the internal temperature in the cooling box 20. The cooling box 20 includes a groove (no shown) to accommodate the resistance temperature detector. The shape of the groove can be set according to the outer contour of the resistance temperature detector. When the temperature in the cooling box 20 is abnormal, the resistance temperature detector can give an alarm to alert the operator that the tank providing cooling by immersion 100 is abnormal. Setting the resistance temperature detector improve the safety performance of the tank providing cooling by immersion 100.

FIG. 3 shows a structural decomposition diagram of an immersion cooling device provided in an embodiment of the present application. The embodiment of the present application also provides an immersion cooling device 400. The immersion cooling device 400 includes the tank providing cooling by immersion 100, the cooling liquid 70 and a liquid supply equipment 60. The cooling liquid 70 is contained in the tank providing cooling by immersion 100. The liquid supply equipment 60 communicates with the tank providing cooling by immersion 100. The liquid supply equipment 60 works to input or output the cooling liquid 70. The tank providing cooling by immersion 100 is any one of the tank providing cooling by immersion 100 provided in the above embodiments.

The immersion cooling device 400 provided above can greatly improve the service life of the product by applying any one of the tank providing cooling by immersion 100 described above to the immersion cooling device 400. The tank providing cooling by immersion 100 adopts the method of the plastic welding, which can greatly improve the production efficiency and reduce the production cost of the product under the premise of the ensuring the product quality. The immersion cooling device 400 includes any one of the tank providing cooling by immersion 100 above embodiments, therefore has all the beneficial effects of the tank providing cooling by immersion 100.

In an embodiment, the liquid supply equipment 60 is a distributor of a cold medium. In other embodiment, the liquid supply equipment 60 also can be replaced with other structures with the same effect and function. The liquid supply equipment 60 can also be a refrigeration distributor.

In an embodiment, the immersion cooling device 400 also includes a fixing seat 200, the immersion cooling box 100 is arranged on the fixing seat 200. The fixing seat 200 is used to fix the immersion cooling box 100 to the specified position.

By setting the immersion cooling box 100 on the fixing seat 60, the immersion cooling device 400 is convenient in movement and installation.

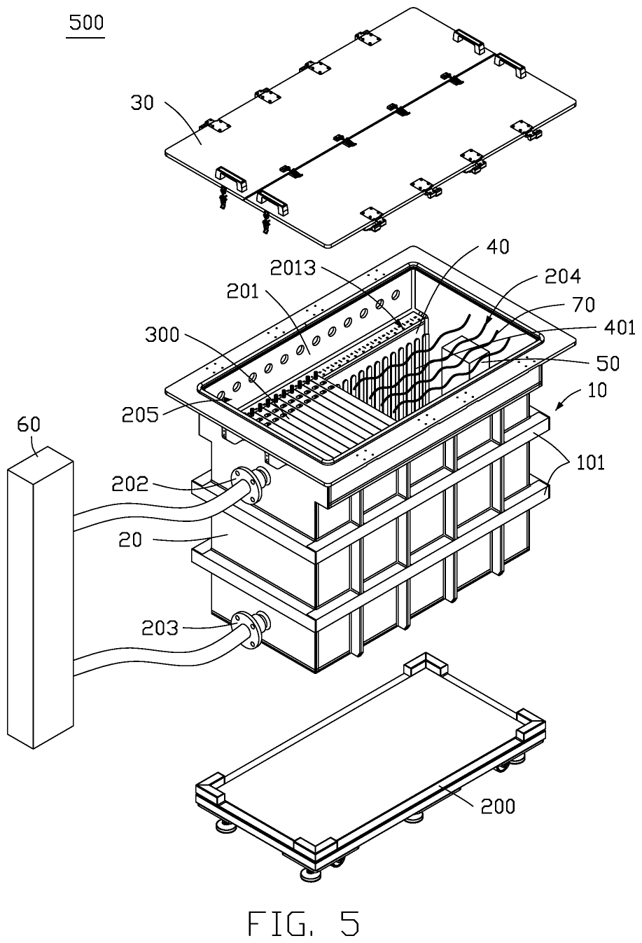

Referring to FIG. 5, in an embodiment, the present application also provides an immersion cooling equipment 500. The immersion cooling equipment 500 includes the immersion cooling device 400, the heating component 300, and the cooling liquid 70 for reducing the temperature of the heating component 300. The tank providing cooling by immersion 100 contains the cooling liquid 70 and the heating component 300, and the heating component 300 is immersed in the cooling liquid 70. The immersion cooling device 400 is the immersion cooling device 400 in the above embodiment therefore has all the beneficial effects of immersion cooling device.

Further, the heating component 300 can be a server. By arranging the server in the cooling liquid 70, the temperature of the server when working is cooled, so as to achieve the effect of heat dissipation. It is understood that in other embodiment, the heating component 300 also can be a other electronic components that generate heat.

By applying the above immersion cooling device 400 to the immersion cooling equipment 500, heat generated by the heating component 300 is removed. The heating component 300 can be immersed in the cooling liquid 70, so the temperature of the heating component 300 is cooled very efficiently. Cooling down the heating component 300 can improve operation efficiency.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A tank configured for providing cooling by immersion, the tank comprising:
a mounting bracket;
a cooling box positioned in the mounting bracket, comprising a plurality of walls defining a reception space, and a first opening communicating with the reception space; and
a sealing plate connected with the cooling box, and configured to open or close the first opening;
wherein each of the plurality of walls is made of thermoplastic plastic, and any two of the walls are connected to each other and fixed by plastic welding.

2. The tank providing cooling by immersion of claim 1, wherein:
the sealing plate is detachably connected the cooling box.

3. The tank providing cooling by immersion of claim 1, wherein:
the sealing plate is rotatably connected the cooling box.

4. The tank providing cooling by immersion of claim 1, wherein:
any two of the plurality of walls abut against each other, two V-shaped welds are formed between the two walls abutting against each another, and weld spot is at the two V-shaped welds.

5. The tank providing cooling by immersion of claim 4, wherein:
the two V-shaped welds comprise a first V-shaped weld and a second V-shaped weld, the first V-shaped weld faces the reception space of the cooling box, and the second V-shaped weld faces an exterior of the cooling box.

6. The tank providing cooling by immersion of claim 1, wherein:
the tank further comprises a fixing mount, the fixing mount is arranged in the cooling box, a fixing groove is defined in the fixing mount and configured for receiving a heating component.

7. The tank providing cooling by immersion of claim 1, wherein:
one of end the sealing plate is hinged to the one of the walls and the sealing plate cover the first opening.

8. The tank providing cooling by immersion of claim 7, wherein:
the sealing plate is made of a transparent material.

9. The tank providing cooling by immersion of claim 7, wherein:
at least one of the plurality of walls is made of a transparent material.

10. The tank providing cooling by immersion of claim 7, wherein:
the sealing plate and at least one wall of the plurality of walls is made of a transparent material.

11. The tank providing cooling by immersion of claim 1, wherein:
an inlet port and an outlet port are defined in the cooling box, and configured to input and output a cooling liquid, respectively;
the wall evenly defines a plurality of through holes, and the plurality of through holes are in communication with the inlet port.

12. The tank providing cooling by immersion of claim 1, wherein:
the tank further comprises a filler, and the filler is positioned in the cooling box, and configured for filling extra space of the cooling box.

13. The tank providing cooling by immersion of claim 1, wherein:
the mounting bracket comprises a plurality of connecting strips, and the connecting strips are attached to a surface of the cooling box.

14. The tank providing cooling by immersion of claim 13, wherein:
the connecting strip is a hollow tubular structure.

15. The tank providing cooling by immersion of claim 13, wherein:
the connecting strip is a solid tubular structure.

16. An immersion cooling device comprising:
a liquid supply equipment; and
a tank configured for providing cooling by immersion, and in communication with the liquid supply equipment, the tank comprising:
a mounting bracket;
a cooling box positioned in the mounting bracket and communicating with the liquid supply equipment, the cooling box comprising a plurality of walls defining a reception space, and a first opening communicating with the reception space; and
a sealing plate connected with the cooling box, and configured to open or close the first opening;
wherein each of the plurality of walls is made of thermoplastic plastic, and any two of the walls are connected to each other and fixed by plastic welding.

17. The immersion cooling device of claim 16, wherein:
any two of the plurality of walls abut against each other, a two V-shaped welds are formed between the two walls abutting against each other, and a welding spot is at the two V-shaped welds.

18. The immersion cooling device of claim 17, wherein:
the two V-shaped welds comprise a first V-shaped weld and a second V-shaped weld, the first V-shaped weld faces the reception space of the cooling box, and the second V-shaped weld faces an exterior of the cooling box.

19. The immersion cooling device of claim 16, wherein:
the tank further comprises a fixing mount, the fixing mount is arranged in the cooling box, a fixing groove is defined in the fixing mount and configured for receiving a heating component.

20. An immersion cooling equipment comprising:
a heating component; and
an immersion cooling device comprising:
a liquid supply equipment; and
a tank in communication with the liquid supply equipment and being configured for accommodating the heating component and cooling liquid, the tank comprising:
a mounting bracket;
a cooling box positioned in the mounting bracket, and comprising a plurality of walls defining a reception space, and a first opening communicating with the reception space; and
a sealing plate connected with the cooling box, and configured to open or close the first opening;
wherein each the plurality of walls is made of thermoplastic plastic, and any two of the walls are connected to each other and fixed by plastic welding.
